(19) United States
(12) Patent Application Publication
(10) Pub. No.: US 2009/0136652 A1
(43) Pub. Date: May 28, 2009

(54) SHOWERHEAD DESIGN WITH PRECURSOR SOURCE

(75) Inventors: Lori D. Washington, Union City, CA (US); Olga Kryliouk, Sunnyvale, CA (US); Yuriy Melnik, Santa Clara, CA (US); Jacob Grayson, Santa Clara, CA (US); Sandeep Nijhawan, Los Altos, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: Applied Materials, Inc.

(21) Appl. No.: 11/925,615

(22) Filed: Oct. 26, 2007

Related U.S. Application Data
(63) Continuation-in-part of application No. 11/767,520, filed on Jun. 24, 2007.

(51) Int. Cl. C23C 16/00; C23C 16/54

(52) U.S. Cl. 427/8; 427/255.28; 118/724; 118/666

(57) ABSTRACT

A method and apparatus that may be utilized in deposition processes, such as hydride vapor phase epitaxial (HVPE) deposition of metal nitride films, are provided. A first set of passages may introduce a metal containing precursor gas. A second set of passages may provide a nitrogen-containing precursor gas. The first and second sets of passages may be interspersed in an effort to separate the metal containing precursor gas and nitrogen-containing precursor gas until they reach a substrate. An inert gas may also be flowed down through the passages to help keep separation and limit reaction at or near the passages, thereby preventing unwanted deposition on the passages.

### CROSS-REFERENCE TO RELATED APPLICATIONS

This is a continuation-in-part of co-pending U.S. patent application Ser. No. 11/767,520 filed Jun. 24, 2007, which is herein incorporated by reference.

### BACKGROUND OF THE INVENTION

1. Field of the Invention

Embodiments of the present invention generally relate to the manufacture of devices, such as light emitting diodes (LEDs), and, more particularly, to a showerhead design for use in hydride vapor phase epitaxial (HVPE) deposition.

2. Description of the Related Art

Group-III nitride semiconductors are finding greater importance in the development and fabrication of a variety of semiconductor devices, such as short wavelength light emitting diodes (LEDs), laser diodes (LDs), and electronic devices including high power, high frequency, high temperature transistors and integrated circuits. One method that has been used to deposit Group-III nitrides is hydride vapor phase epitaxial (HVPE) deposition. In HVPE, a halide reacts with the Group-III metal to form a metal containing precursor (e.g., metal chloride). The metal containing precursor then reacts with a nitrogen-containing gas to form the Group-III metal nitride.

As the demand for LEDs, LDs, transistors and integrated circuits increases, the efficiency of depositing the Group-III metal nitride takes on greater importance. There is a general need for a deposition apparatus and process with a high deposition rate that can deposit films uniformly over a large substrate or multiple substrates. Additionally, uniform precursor mixing is desirable for consistent film quality over the substrate. Therefore, there is a need in the art for an improved HVPE deposition method and an HVPE apparatus.

### SUMMARY OF THE INVENTION

The present invention generally methods and apparatus for gas delivery in deposition processes, such as hydride vapor phase epitaxial (HVPE).

One embodiment provides a method of forming a metal nitride on one or more substrates. The method generally includes introducing a metal containing precursor gas through a first set of passages above the one or more substrates, introducing a nitrogen-containing precursor gas through a second set of passages above the one or more substrates, wherein the second set of passages are interspersed with the first set of passages, and introducing an inert gas above the first and second set of passages towards the one or more substrates to limit reaction of the metal containing precursor gas and nitrogen-containing precursor gas at or near the first and second set of passages.

One embodiment provides a method of forming a metal nitride on one or more substrates. The method generally includes introducing a metal containing precursor gas through a set of passages above the one or more substrates and introducing a nitrogen-containing precursor gas above the set of passages so that the nitrogen-containing precursor gas flows between the set of passages toward the one or more substrates.

One embodiment provides a gas delivery apparatus for a hydride vapor phase epitaxial chamber. The apparatus generally includes a first gas inlet coupled to a metal containing precursor gas source, a second gas inlet separate from the first gas inlet, the second gas inlet coupled to a nitrogen-containing precursor gas source, and one or more third gas inlets separate from the first and second gas inlets, the third gas inlet oriented to direct gas into the chamber in a direction substantially perpendicular to the surface of at least one substrate.

One embodiment provides a gas delivery apparatus for a hydride vapor phase epitaxial chamber. The apparatus generally includes a first gas inlet coupled to a metal containing precursor gas source and a second gas inlet separate from the first gas inlet, the second gas inlet coupled with a nitrogen-containing precursor gas source, wherein the second gas inlet is oriented to direct gas into the chamber in a direction substantially perpendicular to the surface of the at least one substrate.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 is a cross sectional view of a deposition chamber according to one embodiment of the invention.

FIG. 2 is a cross sectional perspective side-view of a showerhead assembly according to one embodiment of the invention.

FIG. 3 is a cross sectional top-view of a showerhead assembly according to one embodiment of the invention.

FIG. 4 is a cross sectional perspective cutaway-view of a showerhead assembly according to one embodiment of the invention.

FIG. 5 is a perspective view of the gas passage components of a showerhead assembly according to one embodiment of the invention.

FIG. 6 is a perspective view of the top plate component of a showerhead assembly according to one embodiment of the invention.

FIG. 7 is a cross sectional perspective side-view of a showerhead assembly according to one embodiment of the invention.

FIG. 8 is a perspective view of the boat components of a showerhead assembly according to one embodiment of the invention.

FIG. 9 is a perspective view of the gas passage components of a showerhead assembly according to one embodiment of the invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

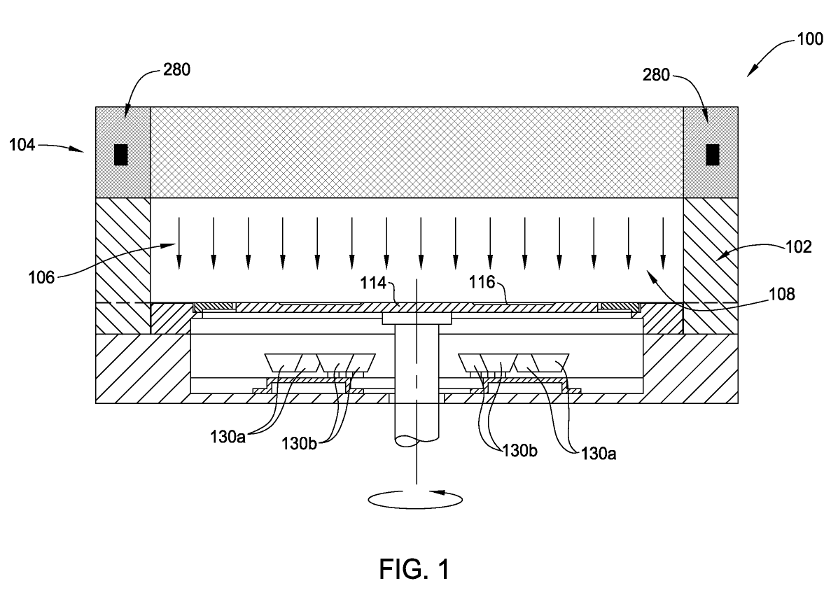

The present invention generally provides a method and apparatus that may be utilized in deposition processes, such as hydride vapor phase epitaxial (HVPE) deposition. FIG. 1 is a schematic cross sectional view of an HVPE chamber that may be used to practice the invention according to one embodiment of the invention. Exemplary chambers that may be adapted to practice the present invention are described in U.S. patent application Ser. Nos. 11/411,672 and 11/404,516, both of which are incorporated by reference in their entireties.

The apparatus 100 in FIG. 1 includes a chamber body 102 that encloses a processing volume 108. A showerhead assembly 104 is disposed at one end of the processing volume 108, and a substrate carrier 114 is disposed at the other end of the processing volume 108. The substrate carrier 114 may include one or more recesses 116 within which one or more substrates may be disposed during processing. The substrate carrier 114 may carry six or more substrates. A susceptor may be positioned below the substrate carrier 114. The susceptor may be made of a thermally conductive material (e.g., silicon carbide) that allows for temperature monitoring and control of the substrate. In one embodiment, the substrate carrier 114 carries eight substrates. It is to be understood that more or less substrates may be carried on the substrate carrier 114. Typical substrates may be sapphire, SiC or silicon. Substrate size may range from 50 mm-100 mm in diameter or larger. The substrate carrier size may range from 200 mm-500 mm. The substrate carrier may be formed from a variety of materials, including SiC or SiC-coated graphite. It is to be understood that the substrates may consist of sapphire, SiC, GaN, silicon, quartz, GaAs, AlN or glass. It is to be understood that substrates of other sizes may be processed within the apparatus 100 and according to the processes described herein. The showerhead assembly, as described above, may allow for more uniform deposition across a greater number of substrates or larger substrates than in traditional HVPE chambers, thereby reducing production costs. The substrate carrier 114 may rotate about its central axis during processing. In one embodiment, the substrates may be individually rotated within the substrate carrier 114.

The substrate carrier 114 may be rotated. In one embodiment, the substrate carrier 114 may be rotated at about 2 RPM to about 100 RPM. In another embodiment, the substrate carrier 114 may be rotated at about 30 RPM. Rotating the substrate carrier 114 aids in providing uniform exposure of the processing gases to each substrate.

A plurality of lamps 130a, 130b may be disposed below the substrate carrier 114. For many applications, a typical lamp arrangement may comprise banks of lamps above (not shown) and below (as shown) the substrate. One embodiment may incorporate lamps from the sides. In certain embodiments, the lamps may be arranged in concentric circles. For example, the inner array of lamps 130b may include eight lamps, and the outer array of lamps 130a may include twelve lamps. In one embodiment of the invention, the lamps 130a, 130b are each individually powered. In another embodiment, arrays of lamps 130a, 130b may be positioned above or within showerhead assembly 104. It is understood that other arrangements and other numbers of lamps are possible. The arrays of lamps 130a, 130b may be selectively powered to heat the inner and outer areas of the substrate carrier 114. In one embodiment, the lamps 130a, 130b are collectively powered as inner and outer arrays in which the top and bottom arrays are either collectively powered or separately powered. In yet another embodiment, separate lamps or heating elements may be positioned over and/or under the source boat 280. It is to be understood that the invention is not restricted to the use of arrays of lamps. Any suitable heating source may be utilized to ensure that the proper temperature is adequately applied to the processing chamber, substrates therein, and a metal source. For example, it is contemplated that a rapid thermal processing lamp system may be utilized such as is described in United States Patent Publication No. 2006/0018639 A1, which is incorporated by reference in its entirety.

One or more lamps 103a, 130b may be powered to heat the substrates as well as the source boat 280. The lamps may heat the substrate to a temperature of about 900 degrees Celsius to about 1200 degrees Celsius. In another embodiment, the lamps 130a, 130b maintain the metal source in well 820 within the source boat 280 at a temperature of about 350 degrees Celsius to about 900 degrees Celsius. A thermocouple may be positioned within the well 820 to measure the metal source temperature during processing. The temperature measured by the thermocouple may be fed back to a controller that adjusts the heat provided from the heating lamps 130a, 130b so that the temperature of the metal source in well 820 may be controlled or adjusted as necessary.

During the process according to one embodiment of the invention, precursor gases 106 flow from the showerhead assembly 104 towards the substrate surface. Reaction of the precursor gases 106 at or near the substrate surface may deposit various metal nitride layers upon the substrate, including GaN, AlN, and InN. Multiple metals may also be utilized for the deposition of “combination films” such as AlGaN and/or InGaN. The processing volume 108 may be maintained at a pressure of about 760 Torr down to about 100 Torr. In one embodiment, the processing volume 108 is maintaining at a pressure of about 450 Torr to about 760 Torr.

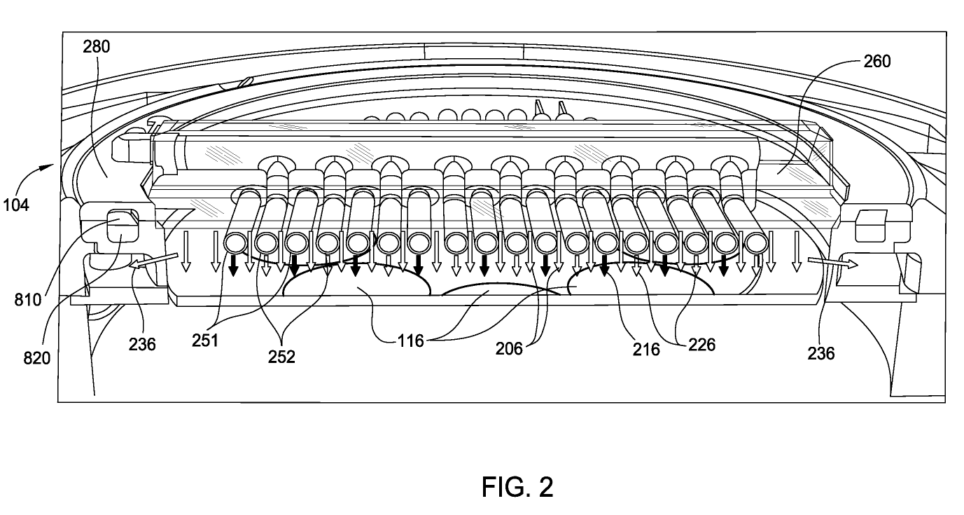

FIG. 2 is a cross sectional perspective of the HVPE chamber of FIG. 1, according to one embodiment of the invention. A source boat 280 encircles the chamber body 102. A metal source fills the well 820 of the source boat 280. In one embodiment, the metal source includes any suitable metal source, such as gallium, aluminum, or indium, with the particular metal selected based on the particular application needs. A halide or halogen gas flows through channel 810 above the metal source in well 820 of the source boat 280 and reacts with the metal source to form a gaseous metal-containing precursor. In one embodiment, HCl reacts with liquid gallium to form gaseous GaCl. In another embodiment, Cl2 reacts with liquid gallium to form GaCl and GaCl3. Additional embodiments of the invention utilize other halides or halogens to attain a metal-containing gas phase precursor. Suitable hydrides include those with composition HX (e.g., with X=Cl, Br, and I) and suitable halogens include Cl2, Br, and I2. For halides, the unbalanced reaction equation is:

HX (gas)+M(liquid metal)−>MX(gas)+H(gas)

where X=Cl, Br, or I and M=Ga, Al, or In. For halogens the equation is:

Z(gas)+M(liquid metal)−>MZ(gas)

where Z=Cl2, Br, I2 and M=Ga, Al, In. Hereafter the gaseous metal containing specie will be referred to as the “metal containing precursor” (e.g., metal chloride).

The metal containing precursor gas 216 from the reaction within the source boat 280 is introduced into the processing volume 108 through a first set of gas passages, such as tubes 251. It is to be understood that metal containing precursor gas 216 may be generated from sources other than source boat 280. A nitrogen-containing gas 226 may be introduced into the processing volume 108 through a second set of gas passages, such as tubes 252. While an arrangement of tubes are shown as an example of a suitable gas distribution structure and may be utilized in some embodiments, a variety of other types of arrangements of different type passages designed to provide gas distribution as described herein may also be utilized for other embodiments. Examples of such an arrangement of passages include a gas distribution structure having (as passages) gas distribution channels formed in a plate, as described in greater detail below.

In one embodiment, the nitrogen-containing gas includes ammonia. The metal containing precursor gas 216 and the nitrogen-containing gas 226 may react near or at the surface of the substrate, and a metal nitride may be deposited onto the substrates. The metal nitride may deposit on the substrates at a rate of about 1 microns per hour to about 60 microns per hour. In one embodiment, the deposition rate is about 15 microns per hour to about 25 microns per hour.

In one embodiment, an inert gas 206 is introduced into the processing volume 108 through plate 260. By flowing inert gas 206 between the metal containing precursor gas 216 and the nitrogen-containing gas 226, the metal containing precursor gas 216 and the nitrogen-containing gas 226 may not contact each other and prematurely react to deposit on undesired surfaces. In one embodiment, the inert gas 206 includes hydrogen, nitrogen, helium, argon or combinations thereof. In another embodiment, ammonia is substituted for the inert gas 206. In one embodiment, the nitrogen-containing gas 226 is provided to the processing volume at a rate of about 1 slm to about 15 slm. In another embodiment, the nitrogen-containing gas 226 is co-flowed with a carrier gas. The carrier gas may include nitrogen gas or hydrogen gas or an inert gas. In one embodiment, the nitrogen-containing gas 226 is co-flowed with a carrier gas which may be provided at a flow rate of about 0 slm to about 15 slm. Typical flowrates for halide or halogen are 5-1000 sccm but may include flowrates up to 5 slm. Carrier gas for the halide/halogen gas may be 0.1-10 slm and comprises the inert gases listed previously. Additional dilution of the halide/halogen/carrier gas mixture may occur with an inert gas from 0-10 slm. Flow rates for inert gas 206 are 5-40 slm. Process pressure varies between 100-1000 torr. Typical substrate temperatures are 500-1200 C.

The inert gas 206, metal containing precursor gas 216, and the nitrogen-containing gas 226 may exit the processing volume 108 through exhausts 236, which may be distributed about the circumference of the processing volume 108. Such a distribution of exhausts 236 may provide for uniform flow of gases across the surface of the substrate.

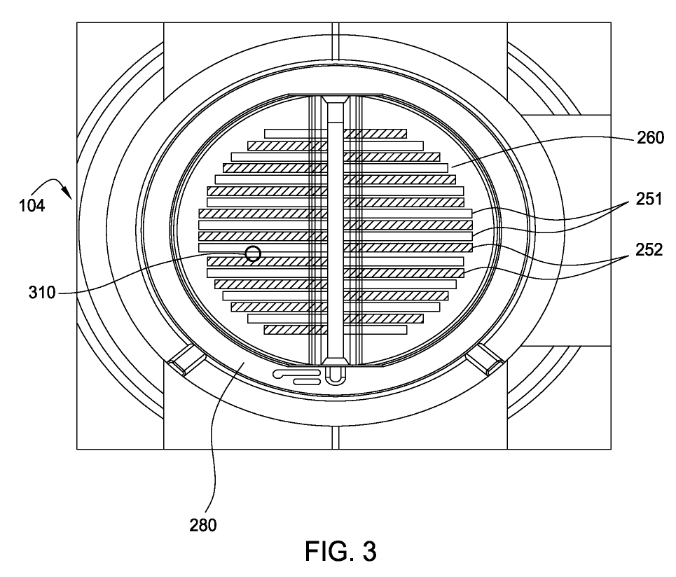

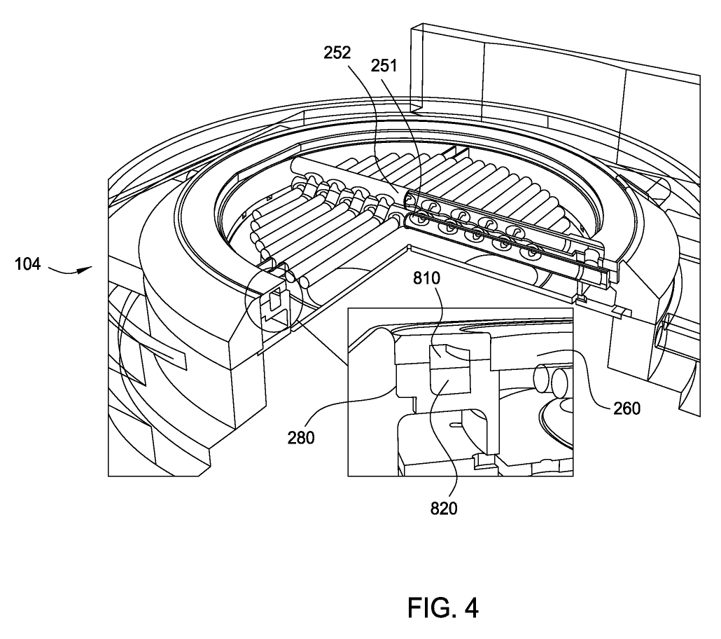

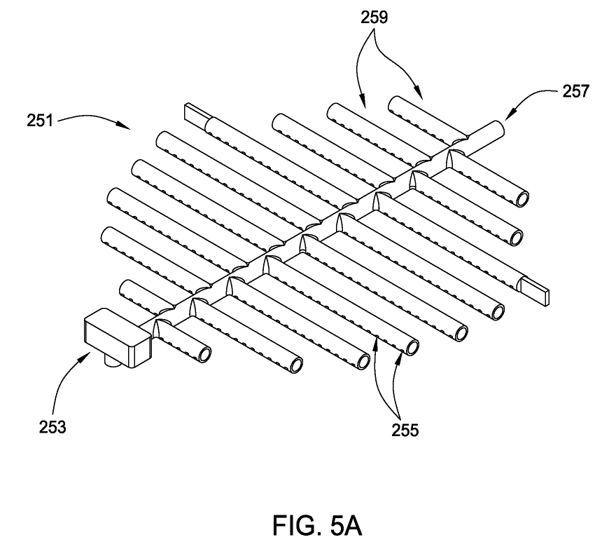

As shown in FIGS. 3 and 4, the gas tubes 251 and gas tubes 252 may be interspersed, according to one embodiment of the invention. The flow rate of the metal containing precursor gas 216 within gas tubes 251 may be controlled independently of the flow rate of the nitrogen-containing gas 226 within gas tubes 252. Independently controlled, interspersed gas tubes may contribute to greater uniformity of distribution of each of the gases across the surface of the substrate, which may provide for greater deposition uniformity.

Additionally, the extent of the reaction between metal containing precursor gas 216 and nitrogen-containing gas 226 will depend on the time the two gases are in contact. By positioning gas tubes 251 and gas tubes 252 parallel to the surface of the substrate, metal containing precursor gas 216 and nitrogen-containing gas 226 will come into contact simultaneously at points equidistant from gas tubes 251 and gas tubes 252, and will therefore react to generally the same extent at all points on the surface of the substrate. Consequently, deposition uniformity can be achieved with substrates of larger diameters. It should be appreciated that variation of distance between the surface of the substrate and gas tubes 251 and gas tubes 252 will govern the extent to which metal containing precursor gas 216 and nitrogen-containing gas 226 will react. Therefore, according to one embodiment of the invention, this dimension of the processing volume 108 may be varied during the deposition process. Also, according to another embodiment of the invention, the distance between gas tubes 251 and the surface of the substrate may be different from the distance between gas tubes 252 and the surface of the substrate. In addition, separation between the gas tubes 251 and 252 may also prevent reaction between the metal containing and nitrogen-containing precursor gases and unwanted deposition at or near the tubes 251 and 252. As will be described below, an inert gas may also be flowed between the tubes 251 and 252 to help maintain separation between the precursor gases.

In one embodiment of the invention, a metrology viewport 310 may be formed in plate 260. This may provide access for radiation measurement instruments to processing volume 108 during processing. Such measurements may be made by an interferometer to determine the rate at which a film is depositing on a substrate by comparing reflected wavelength to transmitted wavelength. Measurements may also be made by a pyrometer to measure substrate temperature. It should be appreciate that metrology viewport 310 may provide access to any radiation measurement instruments commonly used in conjunction with HVPE.

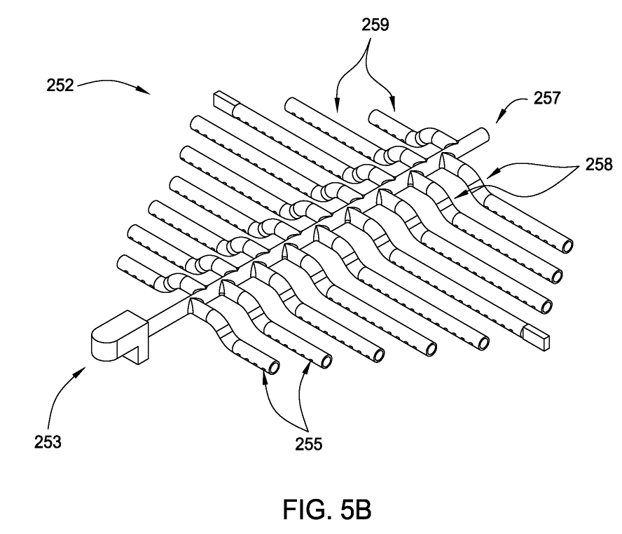

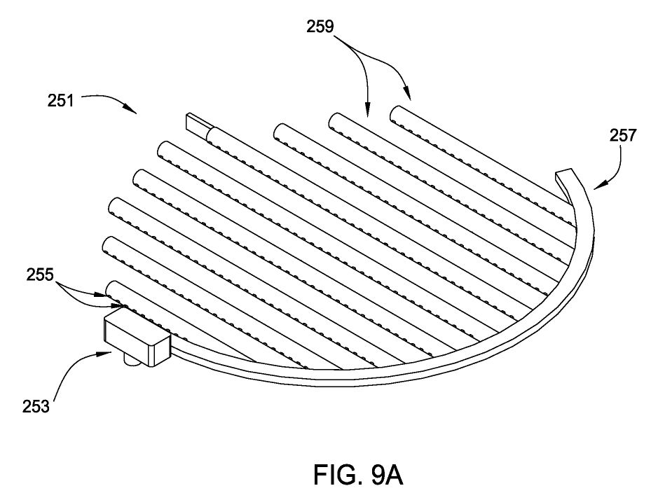

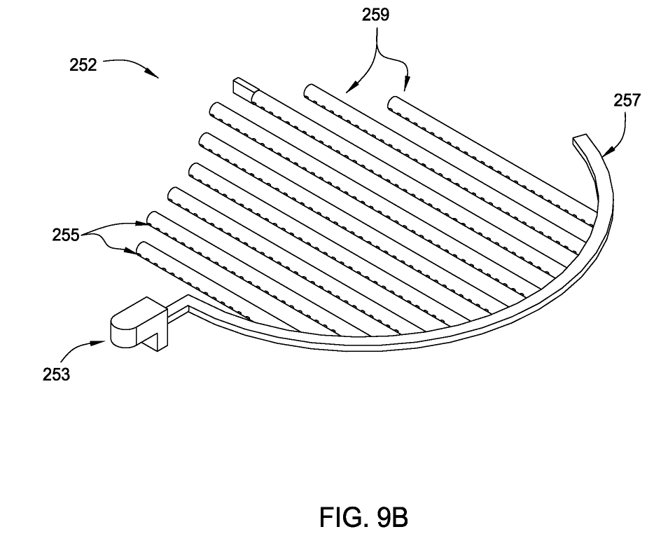

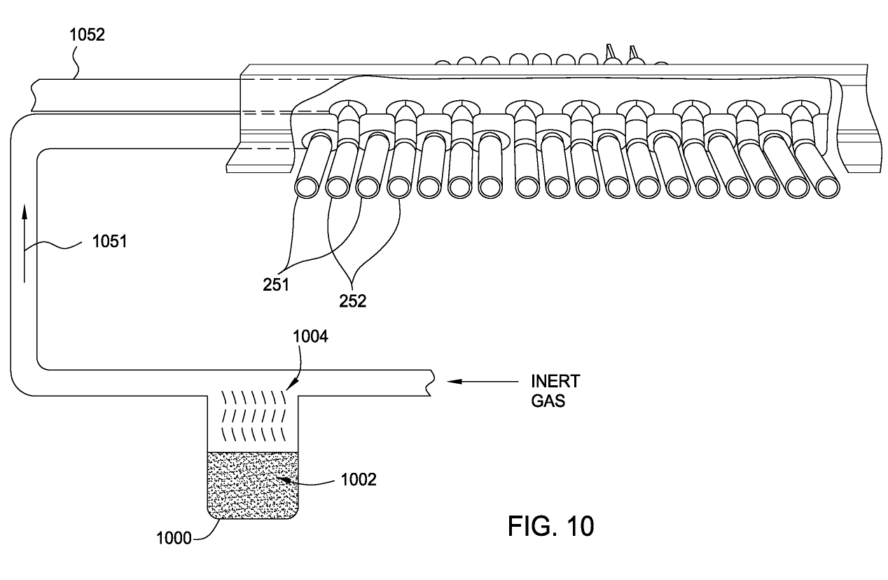

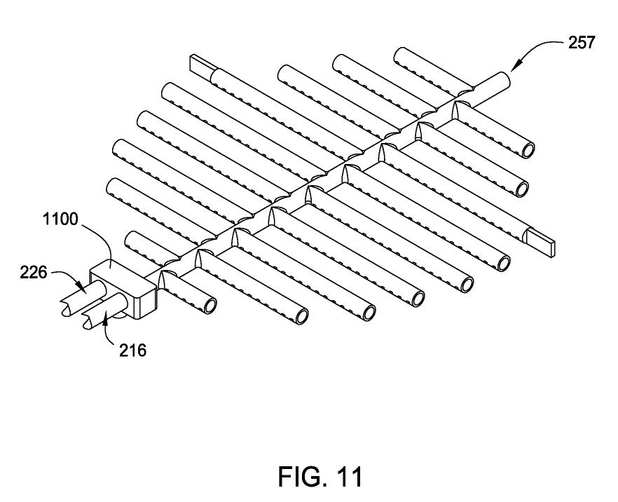

Interspersing of gas tubes 251 and gas tubes 252 may be achieved by constructing the tubes as shown in FIG. 5, according to one embodiment of the invention. Each set of tubes may essentially include a connection port 253, connected to a single trunk tube 257, which is also connected to multiple branch tubes 259. Each of the branch tubes 259 may have multiple gas ports 255 formed on the side of the tubes which generally faces the substrate carrier 114. The connection port 253 of gas tubes 251 may be constructed to be positioned between the connection port 253 of gas tubes 252 and the processing volume 108. The trunk tube 257 of gas tubes 251 would then be positioned between the trunk tube 257 of gas tubes 252 and the processing volume 108. Each branch tube 259 of gas tube 252 may contain an “S” bend 258 close to the connection with trunk tube 257 so that the length of the branch tubes 259 of gas tubes 252 would be parallel to, and aligned with, branch tubes 259 of gas tubes 251. Similarly, interspersing of gas tubes 251 and gas tubes 252 may be achieved by constructing the tubes as shown in FIG. 9, according to another embodiment of the invention which is discussed below. It is to be understood that the number of branch tubes 259, and, consequently, the spacing between adjacent branch tubes, may vary. Larger distances between adjacent branch tubes 259 may reduce premature deposition on the surface of the tubes. Premature deposition may also be reduced by adding partitions between adjacent tubes. The partitions may be positioned perpendicular to the surface of the substrate, or the partitions may be angled so as to direct the gas flows. In one embodiment of the invention, the gas ports 255 may be formed to direct metal containing precursor gas 216 at an angle to nitrogen-containing gas 226.

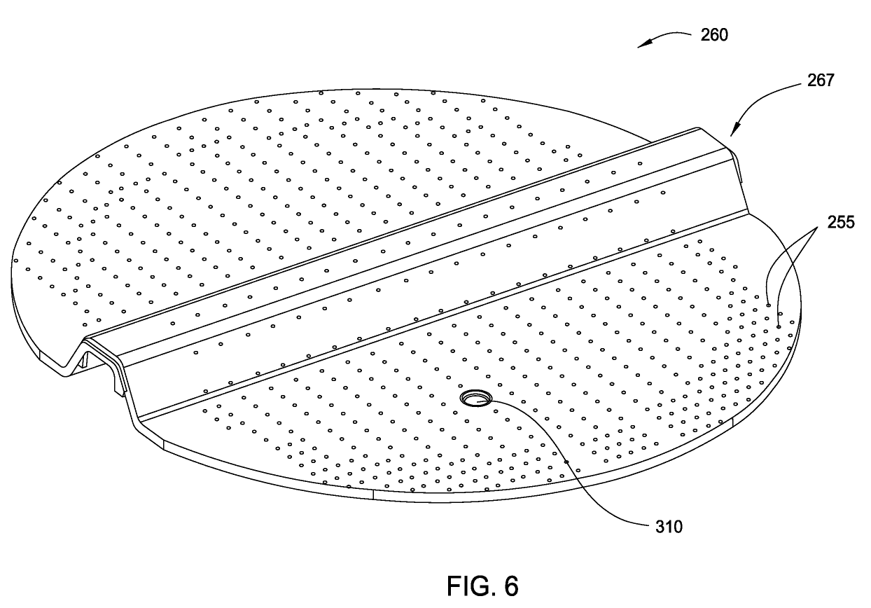

FIG. 6 shows plate 260, according to one embodiment of the invention. As previously described, inert gas 206 may be introduced into the processing volume 108 through multiple gas ports 255 distributed across the surface of plate 260. Notch 267 of plate 260 accommodates the positioning of trunk tube 257 of gas tubes 252, according to one embodiment of the invention. Inert gas 206 may flow between the branch tubes 259 of gas tubes 251 and gas tubes 252, thereby maintaining separation of the flow of metal containing precursor gas 216 from nitrogen-containing gas 226 until the gases approach the surface of the substrate, according to one embodiment of the invention.

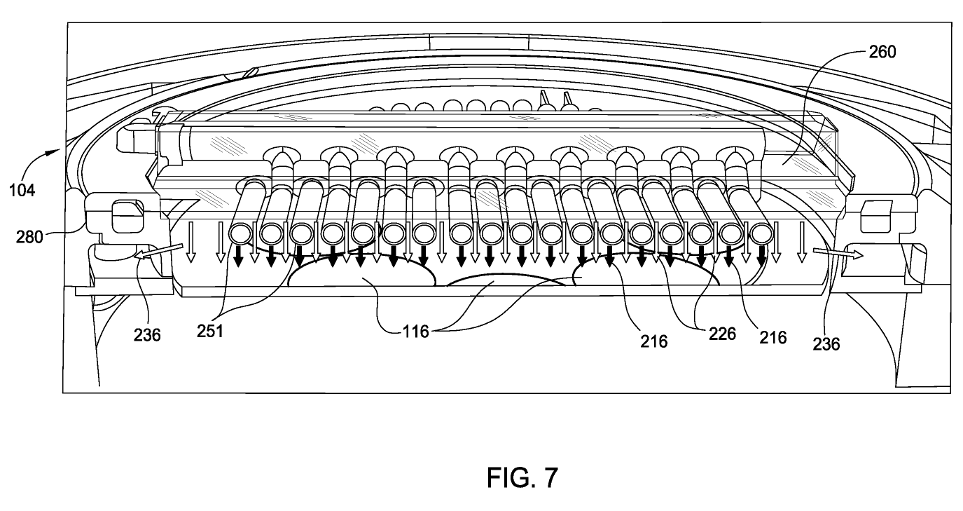

According to one embodiment of the invention, shown in FIG. 7, nitrogen-containing gas 226 may be introduced into processing volume 108 through plate 260. According to this embodiment, branch tubes 259 of gas tubes 252 are replaced by additional branch tubes 259 of gas tube 251. Metal containing precursor gas may thereby be introduced into processing volume 108 through gas tubes 252.

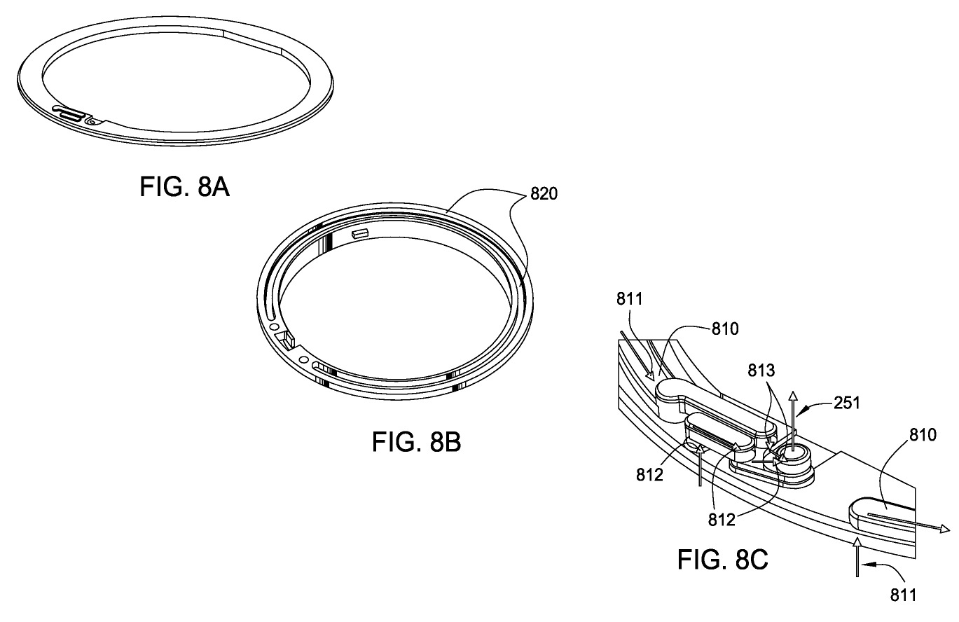

FIG. 8 shows the components of the source boat 280, according to one embodiment of the invention. The boat may be made up of a top portion (FIG. 8A) which covers a bottom portion (FIG. 8B). Joining the two portions creates an annular cavity made up of a channel 810 above a well 820. As previously discussed, chlorine containing gas 811 may flow through the channel 810 and may react with a metal source in the well 820 to produce a metal containing precursor gas 813. According to one embodiment of the invention, metal containing precursor gas 813 may be introduced through gas tubes 251 into processing volume 108 as the metal containing precursor gas 216.

In another embodiment of the invention, metal containing precursor gas 813 may be diluted with inert gas 812 in the dilution port shown in FIG. 8C. Alternatively, inert gas 812 may be added to chlorine containing gas 811 prior to entering channel 810. Additionally, both dilutions may occur; that is, inert gas 812 may be added to chlorine containing gas 811 prior to entering channel 810, and additional inert gas 812 may be added at the exit of channel 810. The diluted metal containing precursor gas is then introduced through gas tubes 251 into processing volume 108 as the metal containing precursor gas 216. The residence time of the chlorine containing gas 811 over the metal source will be directly proportional to the length of the channel 810. Longer residence times generate greater conversion efficiency of the metal containing precursor gas 216. Therefore, by encircling chamber body 102 with source boat 280, a longer channel 810 can be created, resulting in greater conversion efficiency of the metal containing precursor gas 216. A typical diameter of top portion (FIG. 8A) or bottom portion (FIG. 8B), which make up channel 810, is in the range of 10-12 inches. The length of channel 810 is the circumference of top portion (FIG. 8A) and bottom portion (FIG. 8B) and is in the range of 30-40 inches.

FIG. 9 shows another embodiment of the invention. In this embodiment, trunk tubes 257 of gas tubes 251 and 252 may be reconfigured to follow the perimeter of processing volume 108. By moving the trunk tubes 257 to the perimeter, the density of gas ports 255 may become more uniform across the surface of the substrate. It is to be understood that other configurations of trunk tubes 257 and branch tubes 259, with complimentary reconfigurations of plate 260, are possible.

Those skilled in the art will recognize that a variety of modifications may be made from the embodiments described above, while still staying within the scope of the present invention. As an example, as an alternative (or in addition) to an internal boat, some embodiments may utilize a boat that is located outside the chamber. For some such embodiments, a separate heating source and/or heated gas lines may be used to deliver precursor from the external boat to the chamber.

For some embodiments, some type of mechanism may be utilized to all a boat located within a chamber to be refilled (e.g., with liquid metal) without opening the chamber. For example, some type of apparatus utilizing an injector and plunger (e.g., similar to a large-scale syringe) may be located above the boat so that the boat can be refilled with liquid metal without opening the chamber.

For some embodiments, an internal boat may be filled from an external large crucible that is connected to the internal boat. Such a crucible may be heated (e.g., resistively or via lamps) with a separate heating and temperature control system. The crucible may be used to “feed” the boat by various techniques, such as a batch process where an operator opens and closes manual valves, or through the use of process control electronics and mass flow controllers.

For some embodiments, a flash vaporization technique may be utilized to deliver metal precursors into the chamber. For example, flash vaporize metal precursor may be delivered via a liquid injector to inject small amounts of metal into the gas stream.

For some embodiments, some form of temperature control may be utilized to maintain precursor gases in an optimal operating temperature. For example, a boat (whether internal or external) may be fitted with a temperature sensor (e.g., a thermocouple) in direct contact to determine temperature of the precursor in the boat. This temperature sensor may be connected with an automatic feedback temperature control. As an alternative to a directly contacting temperature sensor, remote pyrometry may be utilized to monitor boat temperature.

For an external boat design, a variety of different types of showerhead designs (such as those described above and below) may be utilized. Such showerheads may be constructed from suitable material that can withstand extreme temperatures (e.g., up to 1000° C.) such as SiC or quartz or SiC-coated graphite. As described above, tube temperature may be monitored via thermocouples or remote pyrometry.

For some embodiments, banks of lamps located from top and bottom of chamber may be tuned to adjust tube temperature as necessary to accomplish a variety of goals. Such goals may include minimizing deposition on tubes, maintaining a constant temperature during the deposition process, and ensuring a maximum temperature bound is not exceeded (in order to minimize damage due to thermal stresses).

The components shown in FIGS. 5A-B, 6, 8A-C, and 9A-B may be constructed from any suitable materials, such as SiC, SiC-coated graphite, and/or quartz and may have any suitable physical dimensions. For example, for some embodiments, the showerhead tubes shown in FIGS. 5A-B and 9A-B may have a wall thickness in a range of 1-10 mm (e.g., 2 mm in some applications).

The tubes may also be constructed in a manner that prevents damage from chemical etching and/or corrosion. For example, the tubes may include some type of coating, such as SiC or some other suitable coating that minimizes damage from chemical etching and corrosion. As an alternative, or in addition, the tubes may be surrounded by a separate part that shields the tubes from etching and corrosion. For some embodiments, a main (e.g., center) tube may be quartz while branch tubes may be SiC.

In some applications, there may be a risk of deposits forming on the tubes, which may impede performance, for example, by clogging gas ports. For some embodiments, to prevent or minimize deposition, some type of barrier (e.g., baffles or plates) may be placed between the tubes. Such barriers may be designed to be removable and easily replaceable, thereby facilitating maintenance and repair.

While showerhead designs utilizing branch tubes have been described herein, for some embodiments, the tube construction may be replaced with a different type of construction designed to achieve a similar function. As an example, for some embodiments, delivery channels and holes may be drilled into a single-piece plate that provides a similar function as the tubes in terms of gas separation and delivery into the main chamber. As an alternative, rather than a single piece, a distribution plate may be constructed via multiple parts that can be fit together or assembled in some way (e.g., bonded, welded or braised).

For other embodiments, solid graphite tubes may be formed, coated with SiC, and the graphite may be subsequently removed to leave a series of channels and holes. For some embodiments showerheads may be constructed with various shaped (e.g., elliptical, round, rectangular, or square) clear or opaque quartz plates with holes formed therein. Suitably dimensioned tubing (e.g., channels having 2 mm ID×4 mm OD) may be fused to the plates for gas delivery.

For some embodiments, various components may be made of dissimilar materials. In such cases, measures may be taken in an effort to ensure components fit securely and prevent gas leakage. As an example, for some embodiments, a collar may be used to securely fit a quartz tube into a metal part in order to prevent gas leakage. Such collars may be made of any suitable material, for example, that allows for thermal expansion differences of the dissimilar parts that causes the parts to expand and contract by different amounts, which might otherwise cause damage to the parts or gas leakage.

As described above (e.g., with reference to FIG. 2), halide and halogen gases may be utilized in a deposition process. In addition, the aforementioned halides and halogens may be utilized as etchant gases for in-situ cleaning of the reactor. Such a cleaning process may involve flowing a halide or halogen gas (either with or without an inert carrier gas) into the chamber. At temperatures from 100-1200° C., etchant gases may remove deposition from reactor walls and surfaces. Flow rates of enchant gases vary from 1-20 slm and flow rates of inert carrier gases vary from 0-20 slm. Corresponding pressures may vary from 100-1000 torr and chamber temperature may vary from 20-1200 C.

Further, the aforementioned halide and halogen gases may be utilized in a pretreatment process of substrates, for example, to promote high-quality film growth. One embodiment may involve flowing a halide or halogen gas into the chamber through tubes 251 or through plate 260 without flowing through the boat 280. Inert carrier and/or dilution gases may combine with the halide or halogen gas. Simultaneously NH3 or similar nitrogen containing precursor may flow through tubes 252. Another embodiment of the pretreatment may consist of flowing only a nitrogen-containing precursor with or without inert gases. Additional embodiments may consist of a series of two or more discrete steps, each of which may be different with respect to duration, gases, flowrates, temperature and pressure. Typical flow rates for halide or halogen are 50-1000 sccm but may include flow rates up to 5 slm. Carrier gas for the halide/halogen gas may be 1-40 slm and comprises inert gases listed previously. Additional dilution of the halide/halogen/carrier gas mixture may occur with an inert gas from 0-10 slm. The flowrate of NH3 is between 1-30 slm and is typically greater than the etchant gas flowrate. Process pressure may vary between 100-1000 torr. Typical substrate temperatures are in a range of 500-1200° C.

In addition, Cl2 plasma may be generated for cleaning/deposition processes. Further, chambers described herein may be implemented as part of a multi-chamber system described in co-pending U.S. patent application Ser. No. 11/404,516, which is herein incorporated by reference in its entirety. As described therein, a remote plasma generator may be included as part of the chamber hardware, which can be utilized in the HVPE chamber described herein. Gas lines and process control hardware/software for both deposition and cleaning processes described in the application may also apply to the HVPE chamber described herein. For some embodiments, chlorine-containing gas or plasma may be delivered from above a top plate, such as that shown in FIG. 6, or delivered through tubes that deliver a Ga-containing precursor. The type of plasma that could be utilized is not limited exclusively to chlorine, but may include fluorine, iodine, bromine. The source gases used to generate plasma may be halogens, such as Cl2, Br, I2, or may be gases that contain group 7A elements, such as NF3.

While the foregoing is directed to embodiments of the present invention, other and further embodiments of the invention may be devised without departing from the basic scope thereof, and the scope thereof is determined by the claims that follow.

### Metal Containing Precursor Gas Introduced Without Implementation of a Source Boat

Though in previously mentioned embodiments a metal-containing precursor gas was formed by mixing a halide or halogen gas with a metal source in a source boat, a metal-containing precursor gas may be formed without implementation of a source boat. Such embodiments of the invention may eliminate the need for a source boat 280, thereby simplifying production while maintaining uniformity of metal nitride deposition across the surface of the substrate and limiting depositions on undesired surfaces.

For example, FIG. 10 illustrates one embodiment of the invention, in which an inert gas may flow over an ampoule 1000 containing a solid or liquid form of a Group III tri-chloride 1002 (for example GaCl3). The ampoule may be heated to vaporize the Group III tri-chloride 1004, which is combined with an inert carrier gas to yield a metal containing precursor gas 1051. The metal containing precursor gas may then be provided to the processing volume 108 by way of a first set of gas tubes 251. A nitrogen-containing precursor gas may be introduced into the processing volume 108 through a second set of gas tubes 252. In some embodiments the nitrogen containing precursor gas may contain ammonia.

A typical temperature for vaporizing GaCl3 is 100 degrees Celsius, though GaCl3 may be vaporized between 50 degrees Celsius to 150 degrees Celsius. In some embodiments Group III tri-chloride may be replaced with a Group III tri-iodide or a Group III tri-bromide. In such embodiments the substance may be vaporized between 50 degrees Celsius and 250 degrees Celsius.

### Mixing Metal Containing Precursor Gas with Ammonia Prior to Distribution to Processing Volume

Though in previously mentioned embodiments precursor gases were delivered through separate tubes to a processing volume 108 in which a metal nitride was formed at or near the substrate surface, the metal containing precursor gas and the nitrogen containing precursor gas may be mixed in a mixing zone that allows temperature control between 50 degrees Celsius and 550 degrees Celsius, either within the processing volume, outside the processing volume but inside the processing chamber, or outside the processing chamber entirely, the processing chamber defined as the entire apparatus in FIG. 1. Such embodiments of the invention may (1) improve mixing uniformity and (2) simplify design while (3) minimizing unwanted deposition on surfaces and precursor depletion.

For example, FIG. 11 illustrates one embodiment of the invention, wherein a nitrogen containing precursor gas 226 and a metal containing precursor gas 216 may be mixed within the showerhead assembly 104, in a heated mixing zone 1100, immediately prior to entering a trunk tube 257. In some embodiments, the nitrogen containing gas may include ammonia. In some embodiments, the heated mixing zone may be anywhere between the source of the nitrogen containing precursor gas and metal containing precursor gas and the showerhead. Temperature monitoring and control components may be included in an effort to maintain the heated chamber 1100 at a predetermined temperature, for example, within a temperature range of 50 degrees Celsius to 550 degrees Celsius.

Although only one embodiment of the showerhead tubes is depicted in FIG. 11, those skilled in the art will recognize that a variety of modifications may be made, while still staying within the scope of the present invention. Examples of such modifications may be found in FIGS. 5B, 6, 9A, and 9B.

Though any temperature within the previously mentioned range will suffice, an ideal mixing zone may be maintained at 425 degrees Celsius. It should be noted that temperature control components may be utilized in an effort to set and maintain all parts with surfaces that may be exposed to mixed precursor gases at a predetermined temperature, for example, within a range of 50 degrees Celsius and 550 degrees Celsius, but may ideally be maintained at approximately 425 degrees Celsius for GaCl3. For some embodiments, such control components may allow for collective or independent control of various zones exposed to the precursor gases. These zones include, for example, the mixing zone which may be inside or outside the processing volume (and possibly outside the chamber), chamber parts (e.g., showerhead components), and a zone at or near the substrate (e.g., at or near the susceptor). For embodiments where an ampoule is used for precursor delivery, the ampoule temperature may also be collectively or independently controlled.

For example, a plurality of lamps 130a, 130b may be used to maintain the desired temperature range. In certain embodiments, the lamps may be arranged in concentric circles. For example, the inner array of lamps 130b may include eight lamps, and the outer array of lamps 130a may include twelve lamps. In one embodiment of the invention, the lamps 130a, 130b are each individually powered. In some embodiments, arrays of lamps 130a, 130b may be positioned above or within showerhead assembly 104. It is understood that other arrangements and other number of lamps are possible. It is to be understood that the invention is not restricted to the use of arrays of lamps.

Though the processing volume containing one or more substrates is heated in a fashion similar to that of the mixing zone, the heating of the processing volume is independent of the heating of the mixing zone. In some embodiments, the heating apparatus used to heat the volume may be the same heating apparatus used to heat the substrate. The substrate and susceptor may ideally be heated to 1050 degrees Celsius by a plurality of lamps.

Though previously listed embodiments mention maintaining a temperature using heating lamps, any suitable heating source may be utilized to ensure that the proper temperature is adequately applied to the processing chamber, showerhead, and gaseous precursors.

In addition to the precursors previously mentioned herein, other precursors may be used with showerhead assembly 104. For example, precursors having the general formula MX3 where M is a Group III element (e.g., gallium, aluminum, or indium) and X is a Group VII element (e.g., bromine, chlorine or iodine) may also be used (e.g., GaCl3). Components of the gas delivery system 125 (e.g., bubblers, supply lines) may be suitably adapted to deliver the MX3 precursors to showerhead assembly 104.

While the foregoing is directed to embodiments of the present invention, other and further embodiments of the invention may be devised without departing from the basic scope thereof, and the scope thereof is determined by the claims that follow.

1. A method of forming a Group III-V film on one or more substrates, comprising:
forming one or more metal precursor gases by flowing an inert gas over a solid or liquid Group III metal-containing source;
introducing the one or more metal containing precursor gases through a first set of passages above the one or more substrates; and
introducing a nitrogen containing precursor gas through a second set of passages above the one or more substrates, wherein the second set of passages are interspersed with the first set of passages.

2. The method of claim 1, wherein the Group III metal containing source is an ampoule containing at least one Group III tri-chloride in a solid or liquid state.

3. The method of claim 2, further comprising:
monitoring a temperature of the ampoule containing at least one Group III tri-chloride; and
controlling the temperature of the ampoule based on the monitored temperature of the ampoule.

4. The method of claim 2, wherein the ampoule containing Group III tri-chloride in a solid or liquid state is heated and maintained at a predetermined temperature, wherein the predetermined temperature is in a range between 50 degrees Celsius and 250 degrees Celsius, forming a gaseous Group III tri-chloride.

5. The method of claim 1, wherein the Group III metal containing source comprises:
at least one metal selected from the group consisting of gallium, aluminum and indium; and
at least one Group VII element from the group consisting of chlorine, iodine, and bromine.

6. A gas delivery apparatus for a hydride vapor phase epitaxial chamber, comprising:
an ampoule containing at least one Group III tri-chloride in a solid or liquid state to produce a metal containing precursor gas;
a first set of passages to provide a flow of the metal containing precursor gas; and
a second set of passages to provide a flow of a nitrogen containing precursor gas.

7. The gas delivery apparatus of claim 6, wherein the ampoule containing at least one Group III tri-chloride in a solid or liquid state is heated and maintained at a predetermined temperature, wherein the predetermined temperature is in a range between 50 degrees Celsius and 250 degrees Celsius, to produce a Group III tri-chloride gas.

8. The gas delivery apparatus of claim 7, wherein each of the first and second set of passages comprises:
a hollow trunk tube positioned above the surface of the at least one substrate;
one or more hollow branch tubes fluidly connected to the trunk tube and positioned above and substantially parallel to the surface of the at least one substrate; and
a plurality of gas ports formed in the branch tubes so that the gas in the branch tubes exits the branch tubes toward the at least one substrate;
wherein the branch tubes of the first gas inlet are interspersed with the branch tubes of the second gas inlet.

9. The apparatus of claim 8, wherein the hollow trunk tube and hollow branch tubes are constructed from different materials.

10. The apparatus of claim 8, wherein:
each of the trunk tubes is positioned along an arc formed by a trunk tube; and
each of the branch tubes extend across the chamber, away from the trunk tubes.

11. The apparatus of claim 8, wherein all parts of the apparatus with surfaces that may be exposed to mixed precursor gases are heated and maintained at a predetermined temperature, wherein the predetermined temperature is in a range between 50 degrees Celsius and 550 degree Celsius.

12. The apparatus of claim 6, further comprising:
temperature control components to maintain one or more zones exposed to one or more precursor gases at one or more predetermined temperatures.

13. The apparatus of claim 12, wherein the temperature control components allow for the independent control of at least two of the zones.

14. The apparatus of claim 12, wherein the one or more zones comprise the ampoule.

15. The apparatus of claim 14, wherein the one or more zones further comprise a zone at or near the substrate.
